(19) United States
(12) Patent Application Publication
(10) Pub. No.: US 2014/0069494 A1
(43) Pub. Date: Mar. 13, 2014

(54) METHOD AND APPARATUS FOR INCREASING CONDUCTIVITY OF SOLAR CELL ELECTRODE, AND SOLAR CELL

(71) Applicant: AU OPTRONICS CORPORATION, Hsin-Chu (TW)

(72) Inventors: John Liu, Hsin-Chu (TW); Yi-Jiunn Chien, Hsin-Chu (TW)

(73) Assignee: AU Optronics Corporation, Hsin-Chu (TW)

(21) Appl. No.: 13/684,637

(22) Filed: Nov. 26, 2012

(30) Foreign Application Priority Data
Sep. 12, 2012 (CN) 201210337385.1

(51) Int. Cl. H01L 31/0224; H01L 31/18

(52) U.S. Cl. CPC H01L 31/022433; H01L 31/18
USPC 136/256; 438/98

(57) ABSTRACT

A method and apparatus for increasing conductivity of a solar cell electrode are disclosed. The method includes forming at least one finger on a surface of a substrate, and providing an electrical pulse passing through the finger, in which the duration of the electrical pulse is between 1 microsecond and 1 second. The finger is utilized as an electrode of a solar cell, and includes an adhesive and plural conductive particles blended therein. The temperature of the finger is raised by passing therethrough the electrical pulse to eliminate contaminants and oxidation in the finger and micro-weld the conductive particles in the finger.

### RELATED APPLICATIONS

This application claims priority to China Application Serial Number 201210337385.1, filed Sep. 12, 2012, which is herein incorporated by reference.

### BACKGROUND

1. Field of Invention

The present invention relates to a solar cell. More particularly, the present invention relates to a method and apparatus for fabricating a solar cell.

2. Description of Related Art

In recent years, energy issues have been the focus of much attention. In order to solve the problems associated with using fuel sources to meet energy demands, a variety of alternative energy technologies have been developed. Because solar energy has many advantages, such as being non-polluting and unlimited, it is a popular choice to replace oil energy. Therefore, more and more photovoltaic panels are employed on homes, buildings, etc. at locations where there is abundant sunshine.

The conductivity of the electrodes of a solar cell is determined by the material of the electrodes and the process used to form the electrodes. The substrate of a solar cell can be a silicon substrate coated with an amorphous Si film, and the material of the electrodes can be metal paste (e.g., silver paste), which includes an adhesive and conductive particles blended therein. Voids, contaminants and oxidation may be present on the metal paste, and as a result, the conductivity of the metal paste may be reduced. Therefore, there is a need to improve the conductivity of the electrodes of solar cells.

### SUMMARY

An aspect of the invention provides a method for increasing the conductivity of a solar cell electrode. The method includes forming at least one finger on a surface of a substrate, and providing an electrical pulse along the finger, wherein the duration of the electrical pulse is between 1 microsecond and 1 second. The finger includes an adhesive and plural conductive particles blended therein.

Another aspect of the invention provides a solar cell. The solar cell includes a substrate, and at least one finger disposed on a surface of substrate. The finger includes an adhesive and plural conductive particles blended with the adhesive, and the finger is formed in an open-loop configuration and includes plural contact points.

Another embodiment of the solar cell of the invention includes a substrate, and plural fingers disposed on the substrate. Each of the fingers forms a closed loop.

Another aspect of the invention provides an apparatus for increasing the conductivity of a solar cell electrode. The apparatus for increasing the conductivity of a solar cell electrode includes an electrical pulse source, at least one first conductive probe connecting to a positive electrode of the electrical pulse source, and at least one second conductive probe connecting to a negative electrode of the electrical pulse source.

The local temperature of or within the finger, which is utilized as an electrode of a solar cell, is raised by passing an electrical pulse to eliminate contaminants and oxidation in the finger and micro-weld the conductive particles in the finger, thereby increasing the conductivity of the finger.

It is to be understood that both the foregoing general description and the following detailed description are by examples, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a schematic diagram of an embodiment of a method for increasing conductivity of a solar cell electrode of the invention using an electrical pulse source;

FIG. 2 to FIG. 4 are top views of different embodiments of a solar cell of the invention to be used with the method embodiment of FIG. 1;

FIG. 5 to FIG. 7 are top views of embodiments of a an apparatus for increasing conductivity of a solar cell electrode using an electrical pulse source;

FIG. 8 is a schematic diagram of another embodiment of the method for increasing conductivity of a solar cell electrode of the invention using a varying magnetic field;

FIG. 9 is a schematic diagram of yet another embodiment of the method for increasing conductivity of a solar cell electrode of the invention using a magnetic pulse source;

FIG. 10 and FIG. 11 are top views of different embodiments of the solar cell of the invention for use with the method of FIG. 8 or FIG. 9;

FIG. 12 is a partially enlarged view of a finger before an electrical pulse is passed therethrough; and

FIG. 13 is a partially enlarged view of the finger after an electrical pulse is passed therethrough.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

The disclosure provides a method for increasing conductivity of a solar cell electrode. The method includes raising the temperature to eliminate contaminants and oxidation in a metal paste, and to allow conductive particles to locally reflow and form a micro-weld, thereby increasing the conductivity of the solar cell electrode. Since a substrate has an amorphous Si film thereon, which requires low temperature processing (e.g. <250° C.)., the processing temperature is limited, and as a result, the conductivity of a solar cell electrode cannot be increased by heating the entire solar cell. The method for increasing conductivity of a solar cell electrode of present disclosure partially raises the temperature of the solar cell electrode by passing an electrical pulse therethrough, thereby increasing the conductivity of the solar cell electrode.

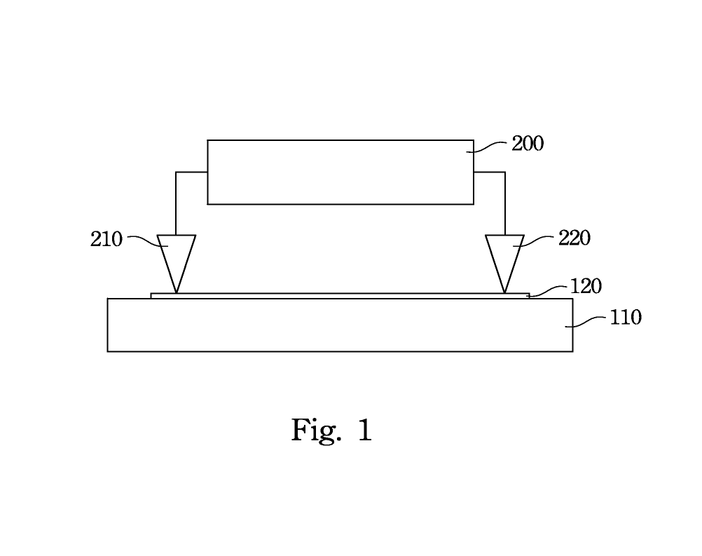

FIG. 1 is a schematic diagram of an embodiment of a method for increasing conductivity of a solar cell electrode of the invention using an electrical pulse source. The method for increasing conductivity of a solar cell electrode includes forming at least one finger 120 on a substrate 110. The finger 120 is made of metal paste, which includes an adhesive and a plurality of conductive particles blended therein. The conductive particles can be metal particles, such as silver or copper. An electrical pulse is provided to pass through the finger 120 to locally raise the temperature of the finger 120. The electrical pulse is a temporary current, and the duration of the electrical pulse is between 1 microsecond and 1 second. The peak current of the electrical pulse is between 3 A and 20 A.

In this embodiment, the electrical pulse is generated by an apparatus for increasing the conductivity of a solar cell electrode. The apparatus for increasing the conductivity of a solar cell electrode includes an electrical pulse source 200, at least one first conductive probe 210, and at least one second conductive probe 220. The first conductive probe 210 is connected to a positive electrode of the electrical pulse source 200. The second conductive probe 220 is connected to a negative electrode of the electrical pulse source 200. The first conductive probe 210 and the second conductive probe 220 are preferably made of soft conductive material to prevent the finger 120 from being damaged during physical contact. For example, the first conductive probe 210 and the second conductive probe 220 can be made of indium. The finger 120 is formed in an open-loop configuration (i.e., the finger 120 does not form a closed loop), and the electrical pulse travels from one end of the finger 120 to another.

The substrate 110 can be a silicon substrate. The substrate 110 may further include an amorphous Si film. The substrate with the amorphous Si film requires low-temperature processing. More particularly, the heating temperature for the substrate 110 with the amorphous Si film is not greater than 250° C. The heating temperature is limited, such that it becomes difficult to raise the temperature of the entire solar cell. The present disclosure partially raises the temperature of the finger 120 with an electrical pulse, i.e., passing through current in a short time. The temperature of the finger 120 is raised through such a process, and as a result, the contaminants and oxidation in the finger 120 can be eliminated. Furthermore, the raised temperature causes the conductive particles in the finger 120 to micro-weld, and thus, the conductivity of the finger 120 can be increased. The process of applying an electrical pulse to the finger 120 can be performed before or after any annealing of the substrate 110.

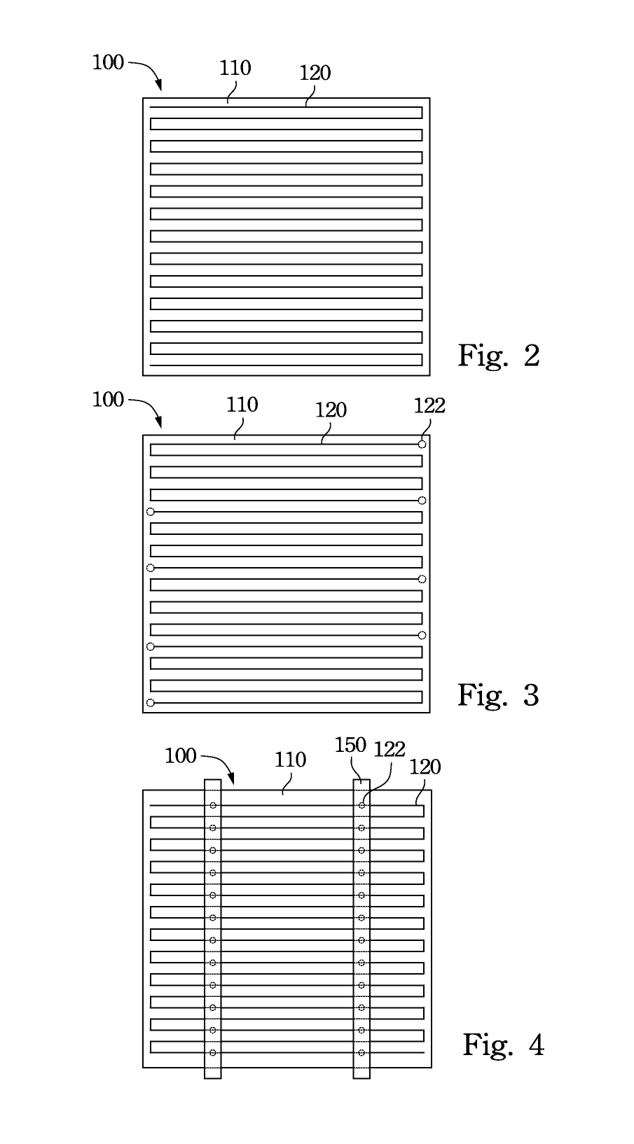

FIG. 2 to FIG. 4 are top views of different embodiments of a solar cell of the invention to be used with the method embodiment of FIG. 1. The solar cells 100 disclosed in FIG. 2 to FIG. 4 are utilized in the method for increasing conductivity of a solar cell electrode as disclosed in FIG. 1.

In FIG. 2, the solar cell 100 includes the substrate 110 and the finger 120 formed on the surface of the substrate 110. The finger 120 is formed in an open-loop configuration (i.e., the finger 120 does not form a closed loop). The pattern of the finger can be linear, zigzag or comb-shaped. The finger 120 can be formed on the substrate 110 continuously, as shown in this embodiment. In other embodiments, the number of the least one finger 120 can be plural, and the fingers 120 are sectionally arranged on the surface of the substrate 110. The first conductive probe 210 and the second conductive probe 220 in FIG. 1 are connected to the opposite ends of the finger 120 respectively.

As shown in FIG. 3, a plurality of the fingers 120 are sectionally arranged on the surface of the substrate 110. The fingers 120 are formed in an open-loop configuration (i.e., the fingers 120 do not form closed loops). Each of the fingers 120 has two contact points 122. The contact points 122 are formed on opposite ends of each of the fingers 120. The width of each of the contact points 122 is greater than that of the body of each of the fingers 120, so that the first conductive probes 210 and the second conductive probes 220 as disclosed in FIG. 1 can contact the contact points 122 easily when the electrical pulse source 200 is connected to the fingers 120.

As shown in FIG. 4, there can be more than two contact points 122 formed on a single finger 120. In order to prevent power loss of the solar cell 100 due to reflection by the contact points 122 which have a large reflecting area, the contact points 122 can be positioned corresponding to predetermined positions of ribbons 150. Namely, the contact points 122 are positioned under the ribbons 150. More particularly, the ribbons 150 are attached to the substrate 110 and the fingers 120 after the electrical pulse is passed through the fingers 120 to increase the conductivity of the fingers 120. The contact points 122 are hidden under the ribbons 150 and therefore power loss does not occur as a result of reflection by the contact points 122.

As is evident from FIG. 2 to FIG. 4, there can be a single finger 120 or plural fingers 120 formed on the substrate 110. The pattern of the finger(s) 120 can be linear, zigzag or comb-shaped. Additionally, each of the fingers 120 may have two or more of the contact points 122. The contact points 122 can be positioned at opposite ends of the fingers 120 or corresponding to the ribbons 150. The voltage required of the electrical pulse source corresponds to the length of the fingers 120. The electrical pulse needs to generate 1-10V/cm to produce the desired current, resulting in at least 1 kV for an approximately 10 m single finger 120. Using plural fingers 120 or more contact points 122 can to reduce the voltage requirement, compared to when using a single finger 120.

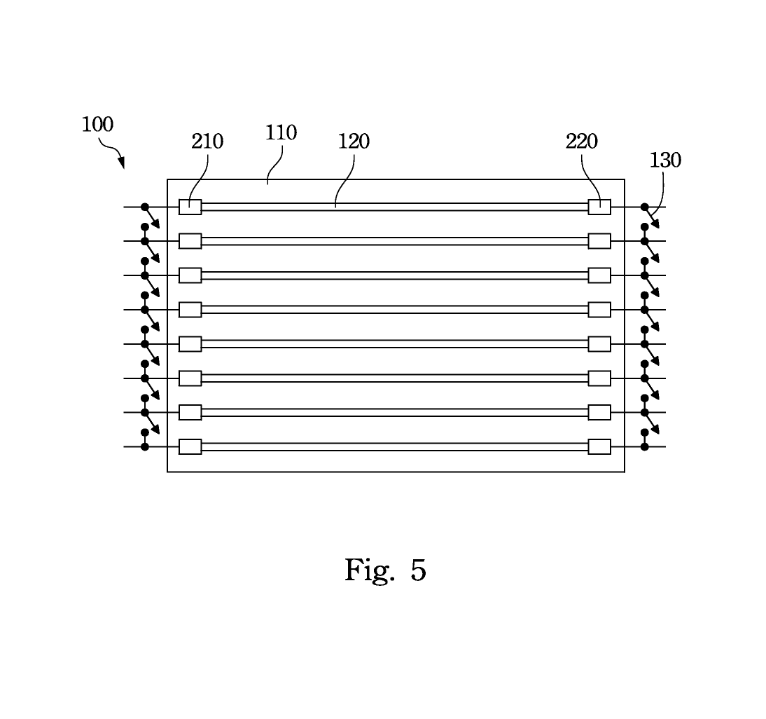

FIG. 5 to FIG. 7 are top views of different embodiments of an apparatus for increasing conductivity of a solar cell electrode using electrical pulses. The apparatus for increasing the conductivity of a solar cell electrode as disclosed in FIG. 1 may further include a plurality of switches 130. The switches 130 are temporarily pressed against the fingers 120.

As shown in FIG. 5, each of the switches 130 is connected to the electrical pulse source (see FIG. 1). Each of the switches 130 controls a first conductive probe 210 or a second conductive probe 220 respectively. The first conductive probes 210 and the second conductive probe 220 are connected respectively to the end of the fingers 120. Each of the first conductive probes 210 or the second conductive probes 220 is connected to one of the fingers 120, and two opposite ends of each of the fingers 120 are connected to the first conductive probe 210 and the second conductive probe 220 respectively. Namely, the fingers 120 are connected to the switches 130 via the first conductive probes 210 and the second conductive probes 220.

The state of each of the switches 130 can be selected individually. The state of each of the switches 130 can be controlled as an open state or a closed state individually thereby selecting a single or a few of the fingers 120 at a time. The first conductive probes 210 and the second conductive probes 220 can be connected respectively to the switches 130 disposed on opposite ends of the fingers 120 (i.e., one of the first conductive probes 210 is connected to one of the switches 130 and one of the second conductive probes 220 is connected to another one of the switches 130). The electrical pulse is transferred to the fingers 120 through the switches 130 with closed states. The fingers 120 through which the electrical pulse is passed therethrough can be designated by controlling the state of the switches 130 during a time interval. The switches 130 can be utilized to actively detect finger defects and actively monitor finger resistance in the solar cell 100. Furthermore the switches 130 can reduce power and peak voltage requirements of the electrical pulse source 200 as disclosed in FIG. 1.

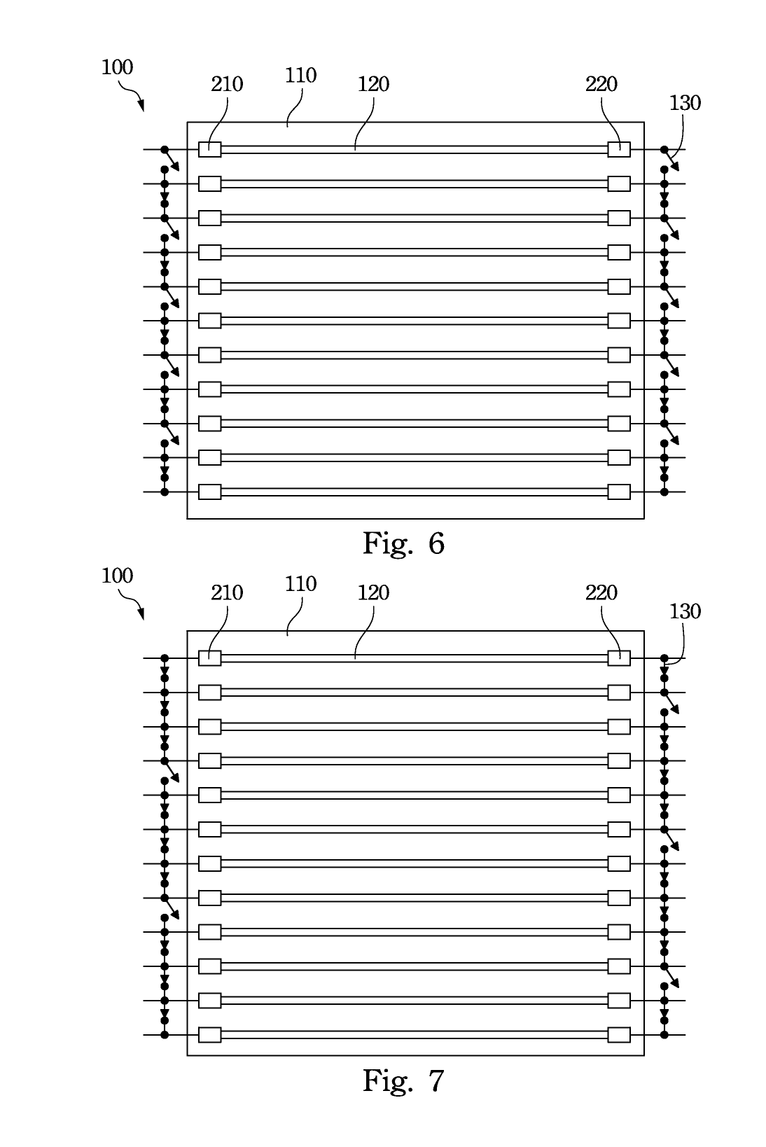

As shown in FIG. 6 and FIG. 7, each of the switches 130 can also be connected to plural fingers 120. In FIG. 6, each of the switches 130 is connected to two of the fingers 120, and the switches 130 do not share the same pair of the fingers 120. A single or a few fingers 120 can be selected by controlling the states of the switches 130. In FIG. 7, each pair of the switches 130 is connected to more than two of the fingers 120. The solar cell 100 in this embodiment can selectively conduct plural fingers 120 at a time.

The switches 130 disclosed in FIG. 6 or FIG. 7 can be utilized to conduct a plurality of the fingers 120 simultaneously. The switches 130 can be utilized to not only actively detect a defect(s) in a group of fingers 120 and actively monitor parallel resistance of a group of fingers 120, but the switches also can reduce power and peak voltage requirements of the electrical pulse source 200 as disclosed in FIG. 1. The method disclosed in FIGS. 6 and 7 can reduce switch and control costs compared the method disclosed in FIG. 5.

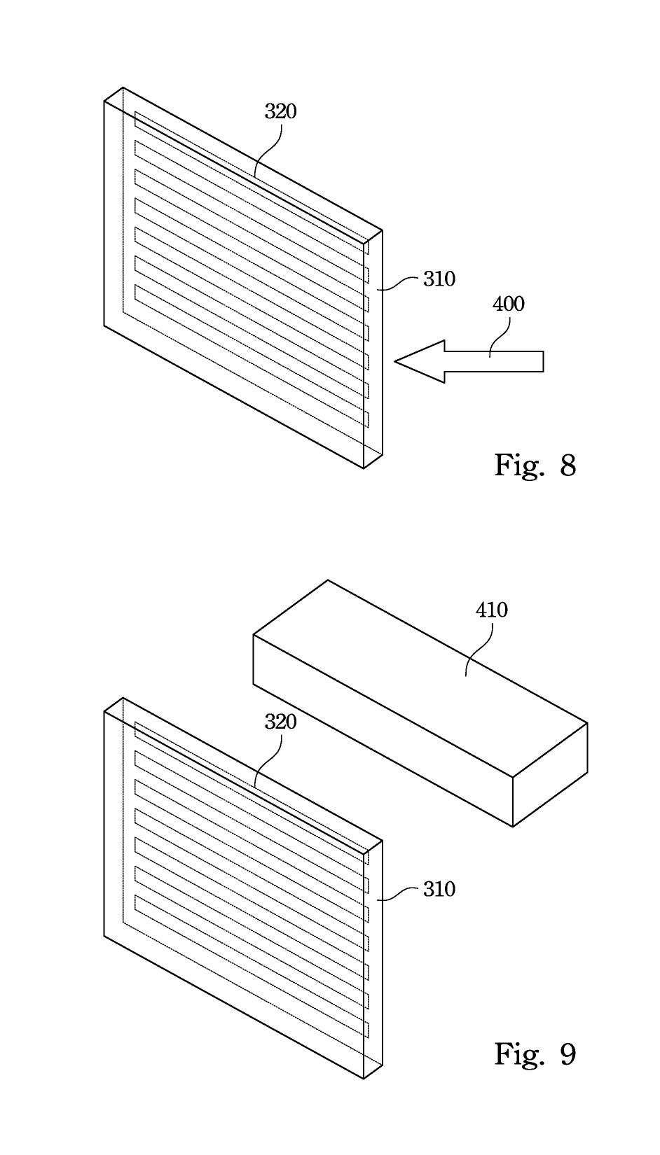

FIG. 8 is a schematic diagram of another embodiment of the method for increasing conductivity of a solar cell electrode of the invention using a varying magnetic field. The method for increasing the conductivity of a solar cell electrode includes forming a plurality of fingers 320 on the surface of the substrate 310. The substrate 310 can be a silicon substrate with an amorphous Si film. The fingers 320 include an adhesive and a plurality of conductive particles blended therein. The conductive particles can be metal particles, such as silver particles or copper particles. The fingers 320 form a plurality of closed loops. The method further includes providing electric pulses along the fingers 320. The duration of the electrical pulses is between 1 microsecond and 1 second.

The electrical pulses can be induced by a varying magnetic field. The step of providing the electrical pulses can involve moving a magnetic field 400 relative to the fingers 320 to thereby generate the electrical pulses passing through the fingers 320, which have closed-loop patterns in this embodiment as described above.

FIG. 9 is a schematic diagram of yet another embodiment of the method for increasing conductivity of a solar cell electrode of the invention using a magnetic pulse source. The method for increasing conductivity of a solar cell electrode includes forming a plurality of fingers 320 on the surface of the substrate 310. The substrate 310 can be a silicon substrate with an amorphous Si film. The fingers 320 include an adhesive and a plurality of conductive particles blended therein. The conductive particles can be metal particles, such as silver particles or copper particles. The fingers 320 form a plurality of closed loops. The method further includes providing electrical pulses along the fingers 320. The duration of the electrical pulses is between 1 microsecond and 1 second.

The electrical pulses are induced currents, which can be generated by magnetic field pulses. The step of providing the electrical pulses includes generating a magnetic pulse by a magnetic field generator 410. The magnetic pulse is a temporary magnetic field, and the duration of the magnetic pulse is between 1 microsecond and 1 second. The variation of magnetic field lines during generation or shutting down of the magnetic field induces the electrical pulses and the currents (electrical pulses) that are passed along the fingers 320, which in this embodiment have closed loop patterns as described above.

The embodiments disclosed in FIG. 8 and FIG. 9 induce currents by magnetic field variation to provide the electrical pulses along the fingers 320. Thus the temperature of the fingers 320 is raised, and the contaminants and oxidation on the conductive particles can be eliminated, thereby increasing the conductivity of the fingers 320. The electrical pulses are induced, as described above, and there is no need for physical contact between conductive probes 210 and 220 and the fingers 120 (as shown in FIG. 1). The non-contact method using a varying magnetic field to induce the electrical pulses can increase yield and efficiency and further prevent the substrate 310 or the fingers 320 from being damaged because of physical contact.

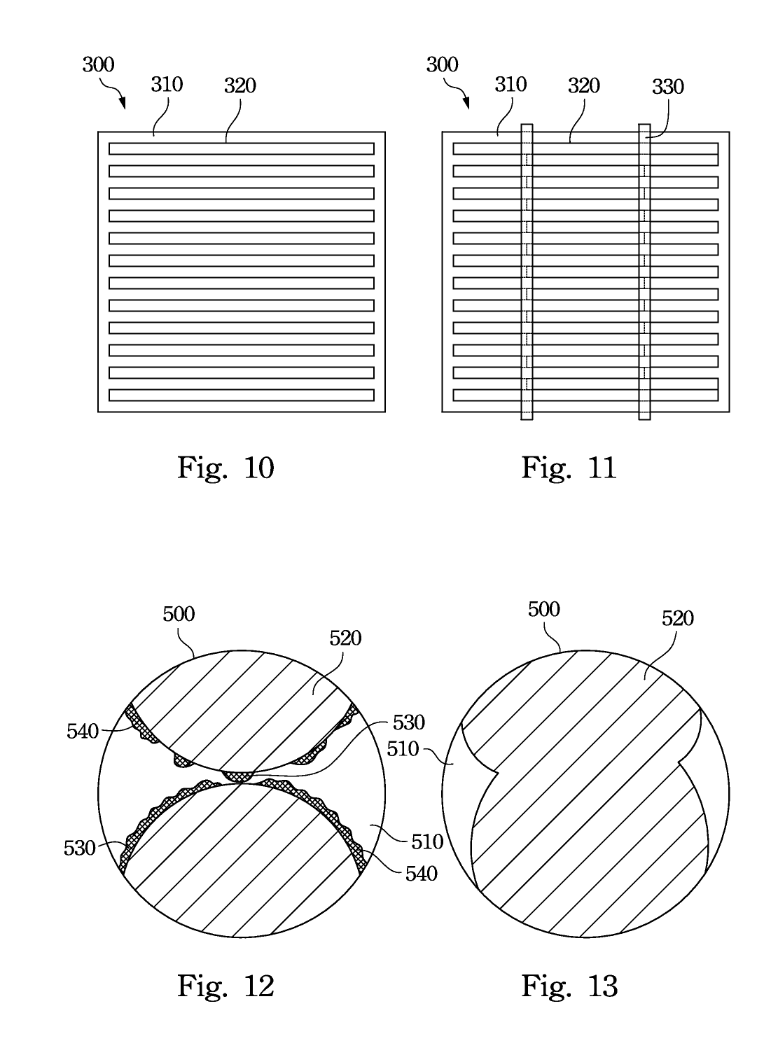

FIG. 10 and FIG. 11 are top views of different embodiments of the solar cell of the invention. The solar cells 300 disclosed in FIG. 10 and FIG. 11 can be utilized in the method as disclosed in FIG. 8 and FIG. 9. Each of the solar cells 300 of FIG. 10 and FIG. 11 has a substrate 310 and a plurality of fingers 320. The substrate 310 can be a silicon substrate with an amorphous Si film. The fingers 320 include an adhesive and a plurality of conductive particles blended therein. The conductive particles can be metal particles, such as silver particles or copper particles. The fingers 320 form a plurality of closed loops. As shown in FIG. 10, the fingers 320 form plural closed loops, and the closed loops are isolated from each other. The size and the shape of the fingers 320 are approximately the same. As shown in FIG. 11, the closed loops formed by the fingers 320 can be connected to each other and still provide a closed loop pattern to generate the induced currents. The fingers 320 in FIG. 11 are alternatingly arranged on the substrate 310. Similar to the embodiment described with reference to FIG. 4, in the embodiment of FIG. 11, in order to prevent power loss due to reflection of the fingers 320, a part of the fingers 320 can be hidden by the ribbons 330. More particularly, the solar cell 300 includes the ribbons 330, and end portions of the closed loops formed by the fingers 320 are disposed under the ribbons 330. As an example, the solar cell 300 includes two ribbons 330, and end portions of the closed loops formed by some of the fingers 320 are disposed under one ribbon 330, while end portions of the closed loops formed by some of the other fingers 320 are disposed under the other ribbon 330.

Reference is now made to both FIG. 12 and FIG. 13. FIG. 12 is a partially enlarged view of a finger before an electrical pulse is passed therethrough, and FIG. 13 is a partially enlarged view of the finger after an electrical pulse is passed therethrough. The finger 500 includes an adhesive 510 and a plurality of conductive particles 520. The conductive particles 520 can be metal particles, such as silver particles or copper particles. As shown in FIG. 12, there are some unwanted contaminants 530 and oxidation 540 adhered on the conductive particles 520 before an electrical pulse is passed through the finger 500, and these contaminants 500 and oxidation 540 reduce the conductivity of the finger 500. After an electrical pulse is passed through the finger 500, the temperature of the finger 500 is raised, and as shown in FIG. 13, the contaminants 530 and oxidation 540 (see FIG. 12) are eliminated, and the conductive particles 520 are micro-welded to each other. Thus the conductivity of finger 500, which is utilized as the electrode of the solar cell, can be increased.

TABLE 1
The electrical conductance of finger after applications of electrical pulse trains

| | before | first electrical | second electrical | third electrical | fourth electrical |
|---|---|---|---|---|---|
| | electrical | pulse train | pulse train | pulse train | pulse train |
| | pulse | application | application | application | application |
| | application | (3 V peak) | (3 V peak) | (4 V peak) | (5 V peak) |
| electrical | 0.15 S | 0.2 S | 0.5 S | 1.0 S | 1.1 S |
| conductance | | | | | |

Table 1 shows the conductance of a finger after an electrical pulse train is applied thereto one to four times. When the first electrical pulse train (the voltage of the strongest electrical pulse is 3V) is passed through the finger and the finger is cooled, the conductance of the finger is 0.2 S (Siemens). When the second electrical pulse train (the voltage of the strongest electrical pulse is 3V) is passed through the finger and the finger is cooled, the conductance of the finger is 0.5 S (Siemens). When the third electrical pulse train (the voltage of the strongest electrical pulse is 4V) is passed through the finger and the finger is cooled, the conductance of the finger is 1.0 S (Siemens). When the fourth electrical pulse train (the voltage of the strongest electrical pulse is 5V) is passed through the finger and the finger is cooled, the conductance of the finger is raised to 1.1S (Siemens). According to this experimental data, the method provided by the invention can increase the conductivity of the finger.

The temperature of the finger is raised by an electrical pulse at the same time eliminating the contaminants and oxidation in the finger and micro-welding the conductive particles in the finger, thereby increasing the conductivity of the finger, which is utilized as the electrode of the solar cell.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for increasing conductivity of a solar cell electrode, the method comprising:
forming at least one finger on a surface of a substrate, wherein the finger comprises an adhesive and a plurality of conductive particles blended therein; and
providing an electrical pulse passing through the finger, wherein a duration of the electrical pulse is between 1 microsecond and 1 second.

2. The method for increasing conductivity of a solar cell electrode of claim 1, wherein a peak current of the electrical pulse is between 3 A and 20 A.

3. The method for increasing conductivity of a solar cell electrode of claim 1, wherein the solar cell comprises an amorphous Si film.

4. The method for increasing conductivity of a solar cell electrode of claim 3, further comprising heating the amorphous Si film, wherein a heating temperature for the amorphous Si film is not greater than 250° C.

5. The method for increasing conductivity of a solar cell electrode of claim 1, wherein the finger is formed in an open-loop configuration and the electrical pulse is generated by an electrical pulse source.

6. The method for increasing conductivity of a solar cell electrode of claim 5, wherein the electrical pulse source is connected to the finger.

7. The method for increasing conductivity of a solar cell electrode of claim 5, further comprising:
using a plurality of switches and probes to connect one or more of the fingers to the pulse source; and
controlling states of the switches to select a single or a few of the fingers at a time.

8. The method for increasing conductivity of a solar cell electrode of claim 1, wherein the finger forms at least one closed loop, and the electrical pulse is induced from a varying magnetic field.

9. The method for increasing conductivity of a solar cell electrode of claim 8, wherein the step of providing the electrical pulse comprises moving a magnetic field relative to the finger.

10. The method for increasing conductivity of a solar cell electrode of claim 8, wherein the step of providing the electrical pulse comprises generating a magnetic pulse.

11. A solar cell comprising:
a substrate; and
at least one finger disposed on a surface of the substrate, wherein the finger comprises an adhesive and a plurality of conductive particles blended with the adhesive, and the finger is formed in an open-loop configuration and comprises a plurality of contact points.

12. The solar cell of claim 11, further comprising a ribbon disposed on the substrate, wherein the contact points are disposed under the ribbon.

13. The solar cell of claim 11, wherein the substrate comprises an amorphous Si film.

14. A solar cell comprising:
a substrate; and
a plurality of fingers disposed on the substrate, wherein each of the fingers forms a closed loop.

15. The solar cell of claim 14, wherein the closed loops are isolated from each other.

16. The solar cell of claim 14, wherein the closed loops are connected to each other.

17. The solar cell of claim 16, wherein the closed loops are alternatingly arranged on the substrate, the solar cell further comprises a ribbon disposed on the substrate, and end portions of the closed loops are disposed under the ribbon.

18. The solar cell of claim 14, wherein the substrate comprises an amorphous Si film.

19. An apparatus for increasing conductivity of solar cell electrode, the apparatus comprising:
an electrical pulse source;
at least one first conductive probe connecting to a positive electrode of the electrical pulse source; and
at least one second conductive probe connecting to a negative electrode of the electrical pulse source.

20. The apparatus for increasing the conductivity of a solar cell electrode of claim 19, further comprising a plurality of switches for being connected to a plurality of fingers through the least one first conductive probe or the least one second conductive probe.

21. The apparatus for increasing the conductivity of a solar cell electrode of claim 20, wherein each of the switches is connected to one of the fingers.

22. The apparatus for increasing the conductivity of a solar cell electrode of claim 20, wherein each of the switches is connected to more than one of the fingers.
